(19) United States
(12) Patent Application Publication
(10) Pub. No.: US 2025/0350266 A1
(43) Pub. Date: Nov. 13, 2025

(54) Voltage-Distributing On-Chip Load Switch (OLS) With Constant-Current Slew Control

(71) Applicant: Google LLC, Mountain View, CA (US)

(72) Inventors: Tong Zhang, Sunnyvale, CA (US); Andrew Masami Abo, San Carlos, CA (US)

(73) Assignee: Google LLC, Mountain View, CA (US)

(21) Appl. No.: 19/227,904

(22) Filed: Jun. 4, 2025

Related U.S. Application Data
(60) Provisional application No. 63/815,301, filed on May 30, 2025.

(51) Int. Cl. H03K 3/012; H03K 17/687

(52) U.S. Cl. CPC H03K 3/012; H03K 17/687

(57) ABSTRACT

This document describes an on-chip load switch (OLS) technology that performs voltage distribution and/or constant-current slew control. The OLS circuit comprises a power input connection that receives the supply voltage, a power output connection that delivers power to other circuits, and a switch core positioned between these connections. The switch core contains an inherent capacitance element, while a connected control circuit generates a constant current that regulates output voltage transition rates. The output voltage slew rate is directly determined by a mathematical relationship between this constant current and the switch core's natural parasitic capacitance.

### CROSS-REFERENCE TO RELATED APPLICATION

This application claims the benefit of U.S. Provisional Patent Application Ser. No. 63/815,301 filed on May 30, 2025, the disclosure of which is incorporated by reference herein in its entirety.

### SUMMARY

This document describes a technology for an on-chip load switch (OLS) that performs voltage distribution and/or constant-current slew control. This technology includes an OLS circuit that includes a power input connection that receives supply voltage; a power output connection that delivers power to other circuits; a switch core placed between these input and output connections that has a capacitance element between its gate and drain; and a control circuit connected to the switch core. The control circuit creates a constant current that regulates how quickly voltage changes at the output. The rate at which the output voltage changes is determined by the relationship between the constant current and the natural capacitance of the switch core.

Another aspect of this technology includes an OLS circuit with a power input node that receives supply voltage from an external source and a power output node, which connects to a destination circuit block that delivers the controlled power. The OLS circuit has a switch core between these nodes that distributes voltage stress across its internal components, which enables operation at or near a defined voltage threshold. The OLS circuit also includes a control circuit, which connects directly to the switch core and operates from a shifted ground reference voltage that facilitates proper voltage-stress distribution throughout the system. The circuit also includes a gate control logic circuit, which provides switching signals and connects to the switch core through established pathways. Furthermore, the OLS circuit includes a coupling capacitor, which forms a feedback path between the switch core and gate control logic, clamping voltage transitions that could otherwise cause instability. The coupling capacitor provides feedback between components that maintain operational stability under varying conditions. The interconnection of these elements creates a functional unit that regulates power delivery with controlled voltage characteristics.

Another aspect of this technology involves an OLS circuit that combines the components and functionality of the above-listed OLS circuits. In addition, such a circuit may perform a method of operating an OLS circuit, which includes the reception of a supply voltage at the power input node. The method facilitates the distribution of voltage stress across internal components of the switch core, which contains a capacitance element that affects electrical characteristics. The control circuit, which operates from a shifted ground reference voltage, facilitates the distribution of voltage stress through the switch core. The gate control logic circuit generates a constant current that controls the slew rate at the power output node, establishing a relationship between this current and the parasitic capacitance that determines the rate of change in the output voltage. The linear voltage rise is independent of an output capacitance of the circuit block. Voltage transitions undergo clamping through the coupling capacitor, which provides feedback between the switch core and gate control logic circuit. The culmination of these operations results in power delivery from the power output node to the circuit block, which receives the regulated supply. This method, which integrates multiple electrical control mechanisms, maintains operational parameters within design specifications that ensure proper circuit function.

This summary is provided to introduce simplified concepts for a technology that utilizes an OLS to perform voltage distribution and constant-current slew control. This technology is further described below in the Detailed Description and Drawings. This summary is not intended to identify essential features of the claimed subject matter, nor is it intended for use in determining the scope of the claimed subject matter.

### BRIEF DESCRIPTION OF THE DRAWINGS

The details of one or more aspects of technology that utilize voltage-distributing on-chip load switch (OLS) with constant-current slew control are described in this document with reference to the following drawings. The same numbers are used throughout the drawings to reference like features and components:

FIG. 1 illustrates an example operating environment in which an on-chip load switch (OLS) can be implemented in accordance with the technology described herein to perform voltage distribution and constant-current slew control.

FIG. 2 illustrates an example on-chip load switch circuitry that can be implemented in accordance with the technology described herein to perform constant-current slew control.

FIG. 3 illustrates a conceptual contrast model of a gate control logic circuit like the gate control logic circuit of example on-chip load switch circuitry of FIG. 2.

FIG. 4 illustrates an example on-chip load switch circuitry that can be implemented in accordance with the technology described herein to perform voltage distribution.

FIG. 5 illustrates an example cascode transistor stack of the switch core of the example OLS circuit of FIG. 4.

FIG. 6 illustrates simplified circuit diagram of a cascode transistor stack with an example coupling capacitor of the example OLS circuit 400 of FIG. 4.

FIG. 7 is a diagram of an example OLS circuit that can be implemented in accordance with the technology described herein to perform voltage distribution and constant-current slew control.

FIG. 8 illustrates an example method for voltage distribution and constant-current slew control by an example OLS circuit in accordance with one or more implementations described herein.

### DETAILED DESCRIPTION

### Overview

A technology described herein is an on-chip load switch (OLS) that performs voltage distribution and constant-current slew control. This OLS operates at a defined voltage (1.2 V) while controlling voltage transition rates during activation and deactivation. The technology generates a constant current with natural transistor capacitance to control output voltage rise and employs stacked transistors to spread voltage stress across multiple internal components operating from a shifted reference point. A well-placed coupling capacitor transforms problematic exponential voltage transitions into controlled linear rises, which prevent false triggering of electrostatic discharge (ESD) protection circuits without using space-consuming bias circuitry.

The OLS disconnects power from inactive circuit blocks residing directly within the semiconductor die. A circuit block, which consists of interconnected transistors and other electronic components, performs a specific function such as signal processing or memory operations. The OLS reduces static leakage current that flows through transistors during periods of inactivity. System-on-Chip (SoC) designs integrate numerous functional blocks onto a single silicon die and use power management techniques that extend battery life in mobile devices such as smartphones and tablets. Static leakage contributes significantly to overall power consumption in advanced semiconductor processes; thus OLS are often used with SoCs.

Fin Field-Effect Transistor (FinFET) technology constitutes a three-dimensional transistor architecture introduced at the 22 nanometer (nm) node. The 22 nm node identifies a specific generation of semiconductor manufacturing technology that traditionally corresponded to the half-pitch of the metal interconnect lines within memory cells. Modern node designations, which no longer directly correlate with physical dimensions, serve as marketing terms that semiconductor manufacturers use to indicate relative generational advancements in transistor density and performance.

FinFETs feature thin silicon fins extending vertically from the substrate surface with gate electrodes wrapping around three sides of each fin. This three-sided gate configuration provides enhanced electrostatic control of the channel region, which reduces short-channel effects observed in traditional planar transistors. Planar designs reached physical limitations that prevented continued scaling at advanced nodes.

Semiconductor process nodes denote manufacturing technology generations with progressively smaller feature sizes, enabling greater transistor density and improved performance characteristics. Manufacturers encountered physical limitations of FinFET architecture when pushing beyond 5 nm fabrication processes, including quantum effects and statistical variability at extremely small dimensions. Gate-All-Around (GAA) transistors emerged as a solution to overcome these limitations by surrounding the channel material completely with gate material, allowing for improved electrostatic control and enabling further miniaturization of transistor dimensions.

Advanced transistor architectures optimize for digital circuit performance operating with binary values, while analog circuits process continuous signal values requiring component matching and predictable behavior. OLS circuits operating at 1.2 V (OLS12) encounter specific challenges in processes designed primarily for low-voltage operation. Transistor scaling reduces physical dimensions of devices including the distance between terminals and insulation thickness, creating structures that cannot withstand higher voltages without experiencing breakdown or reliability degradation. Circuit designers develop techniques that distribute voltage stress across multiple devices to maintain safe operation at higher voltages.

Slew rate, measured in volts per microsecond, defines how quickly voltage changes over time in OLS circuits. OLS circuits that transition from off to on states produce output voltage rises controlled by slew rate parameters, necessitating smooth transitions without oscillations to preserve circuit integrity. Circuit interconnections transmit these voltage changes throughout systems while rapid transitions create electromagnetic interference affecting adjacent sensitive components. OLS circuits with output voltage that rise too quickly can erroneously activate ESD protection mechanisms, which detect voltage spikes that exceed operational norms and redirect potentially damaging current through dedicated pathways, causing unexpected system shutdowns or operational errors that reduce system dependability.

The GAA transistor architecture enables digital circuits to operate at higher speeds with increased density but imposes specific limitations on analog circuit implementations including OLS12 designs. GAA processes lack genuine 1.2 V input-output devices despite specifications for 1.2 V operation needed by existing circuit blocks, creating inherent voltage constraints. Maximum permitted voltages between transistor terminals in GAA technology restrict high-voltage circuit designs, requiring alternative approaches. OLS12 circuits should operate consistently across variable load conditions while precisely regulating output voltage rise time without dedicated reference circuits.

Placement constraints within digital circuits may prevent using conventional bias generation circuits that would normally ensure controlled slew rates, as these circuits require excessive silicon area impractical for this application. Conventional voltage-distributing circuit topologies create periods where output voltage increases exponentially instead of linearly, particularly during initial activation when transistors operate below threshold voltages, requiring specialized techniques to maintain linear voltage transitions throughout all operating conditions.

### Operating Environment

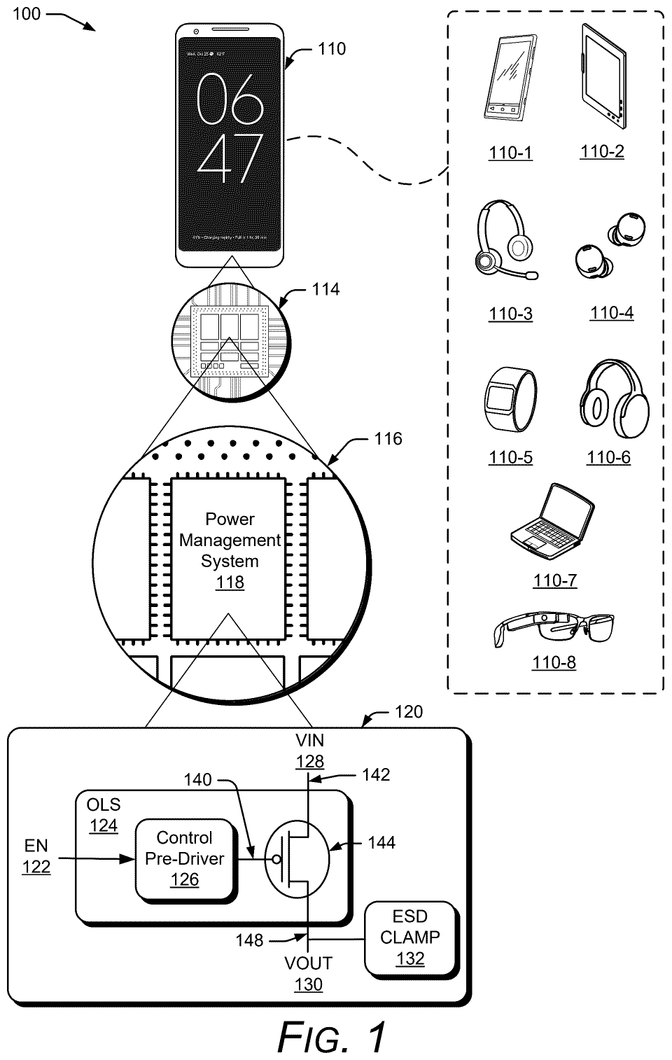

FIG. 1 illustrates an example operating environment 100 in which an on-chip load switch (OLS) can be implemented in accordance with the technology described herein to perform voltage distribution and constant-current slew control. The operating environment 100 includes user equipment 110 (e.g., a smartphone 110-1, tablet 110-2, headset 110-3, earbuds 110-4, wearables 110-5, headphones 110-6, laptop 110-7, smart eyeglasses 110-8, mobile device, wearable device, tablet, or computing device). The user equipment 110 includes integrated circuitry 114, which includes components 116 such as a power management system 118.

Each of the one or more integrated circuitry 114 includes, for example, electronic components 116 fabricated on a single piece of semiconductor material. Such circuits 104 contain multiple electronic elements combined into a unified structure. Examples of implementations of the integrated circuitry 114 include, but are not limited to, system on a chip (SoC), microcontroller units (MCUs), field programmable gate arrays (FPGAs), application specific integrated circuits (ASICs), graphics processing units (GPUs), digital processing units (DPUs), memory management units (MMUs), digital signal processors (DSPs), neural processing units (NPUs), radio frequency integrated circuits (RFICs), power management integrated circuits (PMICs), analog-to-digital converters (ADCs), digital-to-analog converters (DACs), camera image signal processors (ISPs), display controllers, memory controllers, communication interfaces, video processing units (VPUs), artificial intelligence accelerators, mixed-signal integrated circuits, or a combination thereof.

As shown in FIG. 1, the implementation of the integrated circuitry 114 is a System on Chip (SoC), which integrates all electronic components 116 of a computing or electronic system into a single microchip. A typical SoC incorporates a central processing unit (CPU), graphics processing unit (GPU), digital signal processors (DSPs), memory controllers, input/output controllers, audio subsystems, and power management units (e.g., the power management system 118) that function collectively as an integrated computational ecosystem. SoCs frequently include specialized hardware blocks that operate as peripheral macros, such as camera serial interface (CSI), display serial interface (DSI), high-speed input/output (HSIO) interfaces, and image signal processors (ISP). Additional specialized components often found in modern SoCs include multimedia accelerators, neural processing units (NPUs), baseband processors, and sensor hubs, many of which employ on-chip load switch (OLS) technology that enables power conservation through selective supply gating.

The power management system 118 is one of the components 116 of the integrated circuitry 114 that functions as an integrated subsystem that regulates power distribution through multiple specialized circuits, which maintain voltage stability while optimizing energy efficiency across semiconductor components 116. The power management system 118 may transmit control signals to distributed OLS circuits through a power management bus that maintains system-wide power state coherence while supporting domain-specific power gating. OLS circuits, which are positioned at junction points within the power delivery network, interface directly with a voltage regulation subsystem that maintains appropriate voltage levels during dynamic operational transitions.

The power management system 118 incorporates advanced features that enhance energy efficiency through dynamic control mechanisms, which include voltage scaling and clock gating techniques that operate in synchronization with a network of OLS circuits to reduce power consumption during periods of reduced computational demand. OLS circuits positioned at junction points within the power delivery network incorporate integrated voltage monitoring circuits that provide real-time feedback to the power management system 118, which processes this information to maintain optimal voltage levels across varying load conditions while protecting against overcurrent events through built-in current limiting functionality.

FIG. 1 depicts an example on-chip load switch circuitry 120 as part of or connected to the power management system 118. The On-chip load switch circuitry 120 functions as a power gating component within integrated circuits that enable selective power distribution to a circuit block while reducing power consumption during inactive periods. The on-chip load switch circuitry 120 includes an on-chip load switch (OLS) circuit 124 itself, which has a voltage input (VIN) 128, voltage output (VOUT) 130, switch core 144, enable (EN) 122, control pre-driver 126, electrostatic discharge clamp (ESD clamp) 132, and a target circuit block (not shown).

VIN 128 receives external voltage and connects to the OLS circuit 124. VOUT 130 connects to the target circuit block, with voltage levels that vary between zero and the VIN 128 level according to the switch core 144 state. VIN 128 maintains power continuously while VOUT 130 receives power when the OLS circuit 124 activates.

The switch core 144, which connects between VIN 128 and VOUT 130, implements the primary power control function through a source terminal 142 that connects to VIN 128, a gate terminal 140 that receives signals from control pre-driver 140, and a drain terminal 148 that delivers power to VOUT 130. VIN 128 provides the primary supply voltage that passes through the switch core 144, while VOUT 130 delivers controlled power to the target circuit block exclusively during periods when the on-chip load switch circuitry 120 activates the switch core 144.

Control pre-driver 140 converts the digital EN signals 122 into appropriate gate drive voltages for the switch core 144, utilizing level-shifting circuitry that maintains signal integrity across different voltage domains and establishes compatible voltage references. The control pre-driver 140 may implement protection mechanisms that include undervoltage lockout during insufficient supply conditions, current limitation during excessive current detection, and overvoltage protection during supply voltage excursions, which collectively determine both the operational state, and the voltage rise rate at VOUT 130 during activation sequences.

The ESD clamp 132 connects to VOUT 130 and functions through variable-impedance semiconductor devices that transition between high-impedance states during normal operation and low-impedance states when voltage transients exceed predefined thresholds. Semiconductor structures within the ESD clamp 132 establish controlled discharge routes that intercept transient voltages before they reach destructive thresholds for semiconductor junctions in both the switch core 144 and the target circuit block.

The target circuit block receives power through the VOUT 130 connection and operates intermittently according to system operational states, drawing power exclusively when the switch core 144 conducts. EN signals 122 provides the primary control signal that activates or deactivates the power delivery mechanism, which contributes to system-level energy efficiency through elimination of both dynamic and static power consumption in the target circuit block during inactive periods.

### Example OLS Circuit with Constant-Current Slew Control

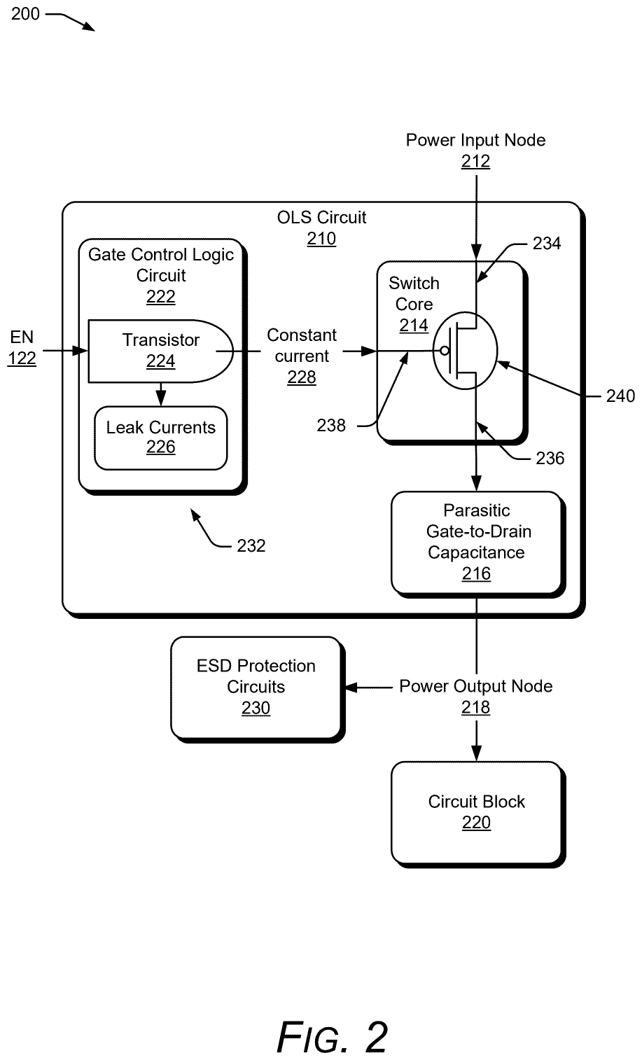

FIG. 2 illustrates an example on-chip load switch circuitry 200 that can be implemented in accordance with the technology described herein to perform constant-current slew control. The example on-chip load switch circuitry 200 includes an OLS circuit 210, a power input (VIN) node 212, a power output (VOUT) node 218, a target circuit block 220, ESD protection circuits 230, and the enable (EN) signal 122. The OLS circuit 210 includes a switch core 214 and a control pre-driver 232.

VIN 212, which functions as the primary voltage supply interface, connects directly to the source terminal 234 of the switch core 214, where it introduces the unregulated supply voltage that will undergo controlled distribution through the OLS circuit 210. VOUT node 218, which is coupled to the drain terminal 236 of the switch core 214, serves as the controlled power delivery point of the OLS circuit 210, providing regulated voltage with a precisely managed slew rate to the target circuit block 220. The target circuit block 220, which remains in a powered-down state during OLS deactivation periods, receives operational voltage exclusively when the switch core 214 transitions to its conductive state.

The target circuit block 220 functions as an integrated electronic subsystem that receives power from the OLS circuit 210 through power output node 218 connection. Operating intermittently according to system operational states, the target circuit block 220 draws power when the switch core 214 conducts, which enables power consumption reduction during periods of inactivity. The selective power delivery mechanism established between the OLS circuit 210 and target circuit block 220 contributes to system-level energy efficiency by eliminating both dynamic and static power consumption in non-essential circuitry.

The ESD protection circuits 230 connects to power output node 218 where it functions as a protective circuit element that transitions between high-impedance and low-impedance states based on output voltage conditions. During normal operation, the ESD protection circuits 230 maintains a high-impedance state that minimizes current leakage through the protection path. When voltage transients at power output node 218 exceed predefined thresholds, the ESD protection circuits 230 activates within nanoseconds, creating a conduction path that diverts excess charge away from sensitive circuit components of the circuit block.

The physical structure of the ESD protection circuits 230 may include semiconductor devices, such as silicon-controlled rectifiers, diodes, or specialized MOSFET configurations that establish controlled discharge routes dimensioned for high current pulse handling. The ESD protection circuits 230 are designed to provide protection against human-body model and machine model discharge events through a response time that intercepts transient voltages before they reach destructive thresholds for semiconductor junctions in the switch core 214 and downstream integrated circuits (e.g., target circuit block 220).

The switch core 214 acts as the main power control element and it includes a switching transistor, which functions as a voltage-controlled current path that modulates conductivity between its source terminal 234 and drain terminal 236 in response to the voltage applied at its gate terminal 238, thereby regulating power transmission from power input node 212 to output node 218. Implementation alternatives for the switching transistor 240 include, for example, metal-oxide-semiconductor field-effect transistors (MOSFETs), which may be configured as N-channel Metal-Oxide-Semiconductor (NMOS) or P-channel Metal-Oxide-Semiconductor (PMOS) variant. Some implementations may employ PMOS transistors for certain power control applications due to their body-effect characteristics and threshold voltage considerations. Some implementations may employ NMOS implementations for reduced on-resistance per unit area for specific voltage ranges.

The source terminal 234 of the switch core 214 is connected to the power input node 212. The gate terminal 238 of the switch core 214 is connected to the output of the control pre-driver 232. The drain terminal 236 of the switch core 214 is connected to the power output node 218. The switch core 214 functions as the switch that controls current flow between power input node 212 and power output node 218 based on the voltage applied to its gate terminal 238.

The switch core 214 has a capacitance element 216, which represents a capacitance that affects the circuit behavior of the switch core 214. The capacitance element 216 may include discrete capacitor components intentionally placed within the circuit, parasitic capacitances that occur naturally between conducting elements (such as capacitance element in MOSFETs), Miller capacitance resulting from feedback effects (which includes both intentional and parasitic components), or a combination of these capacitive sources.

A natural parasitic capacitance element is an inherent electrical characteristic between the gate terminal 238 and drain terminal 236 of the switching transistor 240. The parasitic capacitance element represents a non-ideal capacitive coupling that occurs due to the physical structure and fabrication properties of the semiconductor device. The parasitic capacitance element manifests as overlapping charge regions within the transistor structure and metal interconnections, wherein charge accumulation at the gate influences the drain potential through capacitive coupling mechanisms.

The magnitude of the capacitance element 216 depends on multiple physical parameters, including the gate oxide thickness, the overlap area between gate and drain regions, and the doping profile of the semiconductor material, wire-to-wire capacitance, which collectively determine its contribution to circuit behavior during switching transitions. Depending on the specifics of the implementation, the capacitance of the capacitance element 216 may be measured in the tens to thousands of femtofarads, scaling in proportion to transistor size and current capacity.

The control pre-driver 232 operates as an interface circuit that converts digital enable signals, such as EN signals 122, into appropriate gate drive voltages for the switch core 214. Positioned between the enable input and gate terminal 238, the control pre-driver 232 processes control commands while maintaining signal integrity across potentially different voltage domains. In certain implementations, the control pre-driver 232 includes a level-shifting circuitry that establishes voltage references compatible with system power domains, ensuring compatibility between digital control logic and power transistor specifications through defined operational voltage limits.

The control pre-driver 232 includes a gate control logic circuit 222. The gate control logic circuit 222, which connects between the EN signals 122 input and the gate terminal 238 of the switching transistor 240, generates a constant current 228 that controls the slew rate at the power output node 218 through a direct relationship with the capacitance element 216. The gate control logic circuit 222 receives digital control signals (e.g., EN signals 122) that initiate power state transitions. The gate control logic circuit then transforms binary input commands into analog current profiles, which determine the gate charging characteristics.

Together, the switch core 214 and the gate control logic circuit 222 establish a linear voltage rise at the power output node 218 during activation through a relationship between current and capacitance. The controlled charging of the capacitance element 216 by the constant current 228 from the gate control logic circuit 222 determines the voltage transition rate, creating a predictable and consistent rate of change.

The gate control logic circuit 222 implements a constant-current mechanism through multiple potential topologies, which serve to establish control over gate charging characteristics. The implementation alternatives include various circuit architectures that achieve functionally equivalent constant-current capabilities through fundamentally different electronic principles, enabling adaptation to specific design constraints while maintaining the core functionality required for controlled voltage transitions at the power output node 218.

Gate control logic circuit 222 exhibits leakage currents 226, which represent non-ideal current flows occurring through semiconductor structures when charge carriers traverse nominally insulating barriers under non-conductive operating conditions. These parasitic currents, categorized as I_leak1 and I_leak2, originate from quantum-mechanical electron transport mechanisms that become increasingly significant in advanced semiconductor nodes with reduced physical dimensions. The I_leak1 component manifests through gate oxide tunneling phenomena, wherein electrons traverse the dielectric barrier through quantum mechanical pathways despite the absence of classical conduction mechanisms, while I_leak2 encompasses subthreshold conduction that occurs when transistors operate in the weak inversion region below their nominal threshold voltage parameters.

The physical mechanisms enabling these leakage paths include quantum tunneling through thin oxide barriers, thermionic emission across semiconductor junctions, trap-assisted tunneling through defect states, and band-to-band tunneling in heavily doped regions, all of which increase in magnitude as device dimensions shrink in advanced technology nodes. Temperature-dependent behavior characterizes these leakage currents 226, which exhibit an exponential relationship where current magnitude increases by a factor of approximately two times for every 10° C. temperature increase. The gate control logic circuit 222 implemented here may have an intentional gate charging current (I_gate) exceeds the combined leakage components (I_leak1+I_leak2) by a sufficient margin to maintain deterministic operation across process, voltage, and temperature variations.

The control pre-driver 232 may implement functions related to voltage transition control and device protection within the OLS circuit 210. The control pre-driver 232 may incorporate undervoltage lockout protection that disables switching activity when supply voltages fall below predetermined thresholds, preventing potential damage to connected components. Current limitation capabilities within the control pre-driver 232 may modify gate drive characteristics when excessive current conditions are detected, ensuring the switch core 214 remains within specified operating parameters. The control pre-driver 232 may provide overvoltage protection through signal clamping or disabling during supply voltage excursions, thereby maintaining the integrity of the power path during transient events.

EN signals 122 provides the control signal input connected to the control pre-driver 232, determining when the OLS circuit 210 should turn on or off, with high activation allowing current flow and low deactivation blocking power transmission. The control pre-driver 232 receives the EN signals 122 and connects to the gate terminal 238 of the switch core 214, processing the enable signal to generate appropriate gate voltages that control both the on/off state and the rate at which power output node 218 rises during activation.

The OLS circuit 210 utilizes a slew-rate control mechanism wherein the gate control logic circuit 222 connects to the switch core 214 and provides controlled current flow that influences transitional characteristics at the power output node 218. The switch core 214, positioned between the power input node 212 and the power output node 218, includes the capacitance element 216 that exists between the gate terminal 238 and drain terminal 236 of the switching transistor 240. This configuration enables management of power delivery timing characteristics while maintaining compatibility with system protection specifications.

The switch core 214 works in conjunction with the gate control logic circuit 222 to create a linear voltage rise at the power output node 218 during activation phases, which maintains the voltage transition within a predetermined range that prevents false triggering of the ESD protection circuits 230. These ESD protection circuits 230, connected to the power output node 218, shift between high-impedance and low-impedance states based on output voltage conditions and require carefully managed voltage rise times to avoid inadvertent activation during normal power sequencing operations. The power output node 218 delivers regulated voltage with a controlled slew rate to the target circuit block 220, which stays in a powered-down state when the OLS circuit 210 remains inactive and receives operational voltage when the switch core 214 enters its conductive state.

The gate control logic circuit 222 may include a transistor 224 with a large length-to-width ratio that functions as a resistive element generating the constant current 228 without dedicated bias circuits. The constant current 228 generated by gate control logic circuit 222 maintains a magnitude that deliberately exceeds leakage currents 226, which emerge through dual quantum-mechanical pathways designated as I_leak1 and I_leak2. While I_leak1 manifests when electrons traverse gate oxide dielectrics despite their nominal insulating properties, I_leak2 results from subthreshold conduction occurring in transistors that operate below their designated threshold voltage yet continue to permit measurable current flow. The leakage currents 226, which demonstrate temperature sensitivity characterized by current doubling with each 10° C. ambient increase, establish constraints that circuit designers accommodate through sufficient current margin allocation. The relationship between intentional gate charging current and cumulative leakage phenomena, which defines operational reliability across process, voltage, and temperature variations, enables deterministic control of switch core 214 gate terminal charging characteristics without requiring complex compensatory mechanisms. Circuit stability under varying environmental conditions depends on maintaining this current differential, which serves as the quantifiable parameter governing slew rate consistency across the operational temperature range.

The value of the capacitance of the capacitance element 216 depends on multiple physical parameters, including gate oxide thickness, overlap area between gate and drain regions, and semiconductor material doping profile, metal interconnections, which together determine how this capacitance affects circuit behavior during switching transitions. The switch core 214 features a metal-oxide-semiconductor field-effect transistor (MOSFET), and the capacitance element 216, where the switching transistor 240 acts as a voltage-controlled current path that adjusts conductivity between its source terminal 234 and drain terminal 236 based on voltage applied at its gate terminal 238. The gate control logic circuit 222 maintains the slew rate at the power output node 218 within design parameters, delivering controlled voltage transitions that enable reliable power sequencing for the target circuit block 220.

### Conceptual Contrast Model of a Gate Control Logic Circuit

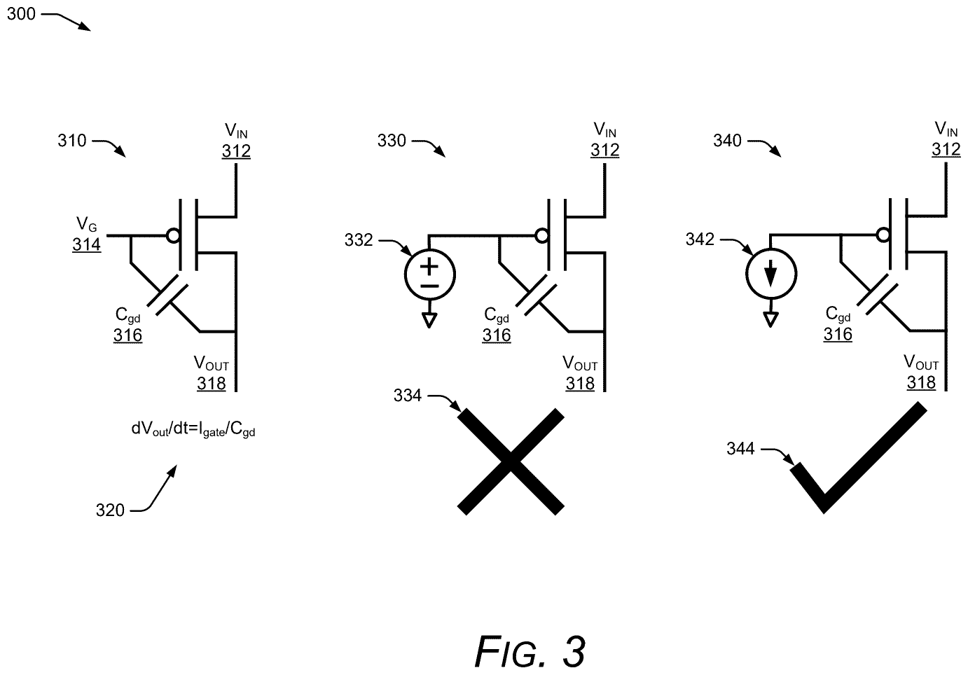

FIG. 3 illustrates a conceptual contrast model 300 of a gate control logic circuit like the gate control logic circuit 222 of the example on-chip load switch circuitry 200 of FIG. 2. The conceptual contrast model 300 demonstrates a relationship between gate voltage (V_{G}) 314, capacitance element (C_{gd}) 316 (e.g., parasitic capacitance element), and output voltage transition rates in power switching applications. The conceptual contrast model 300 includes three alternative circuit topologies: a conceptual model 310, an incorrect example implementation 330, and a correct example implementation 340. The conceptual contrast model 300 is a structured pedagogical approach that enhances understanding through explicit comparison of correct and incorrect implementations.

The first configuration is a conceptual model 310 of a gate control logic circuit like the gate control logic circuit 222 of the example on-chip load switch circuitry 200 of FIG. 2. The conceptual model 310 establishes the conceptual foundation by depicting a switching transistor with voltage input (Vᵢₙ) 312 at its source node, voltage output (Vout) 318 at its drain node, and gate voltage (V_{G}) 314 at gate node. The switching transistor is depicted with its C_{gd} 316 explicitly shown as a discrete component.

The mathematical relationship 320 of the output voltage transition speed may be represented by this equation:

dVₒᵤₜ/dt=I_{gate}/C_{gd}

where dVₒᵤₜ/dt represents the rate of change in output voltage (e.g., slew rate), I_{gate} denotes the constant current supplied to the gate terminal, and C_{gd} signifies the capacitance element.

Slew rate quantifies voltage change velocity in electrical circuits, measuring transition speed in units like volts per microsecond, while output voltage transition encompasses the complete voltage evolution profile from initial to final state. The relationship positions slew rate as a specific numerical parameter that characterizes the broader output voltage transition phenomenon, which includes both quantitative and qualitative waveform attributes.

The mathematical relationship 320 governs how current through the capacitance element C_{gd} 316 directly influences output voltage transition speed. The rate of voltage change at the output node directly correlates to the ratio of the constant current supplied by the gate control logic circuit divided by the value of the capacitance element C_{gd} 316, which creates a proportional relationship where doubling the current doubles the slew rate while doubling the capacitance halves the slew rate. This quantifiable relationship demonstrates that the slew rate varies directly with applied current and inversely with capacitance value, enabling design of power sequencing characteristics that maintain consistency across process, voltage, and temperature variations while requiring minimal implementation complexity.

The second configuration is an incorrect example implementation 330 of a gate control logic circuit like the gate control logic circuit 222 of the on-chip load switch circuitry 200 of FIG. 2. The incorrect example implementation 330 is deliberately marked as incorrect with a visual indicator like an “X” 334. Like the conceptual model 310, the incorrect example implementation 330 has a switching transistor with Vᵢₙ 312 at its source node, Vₒᵤₜ 318 at its drain node, and its intrinsic capacitance element C_{gd} 316 explicitly shown as a discrete component.

The incorrect example implementation 330 implements a voltage-controlled gate drive mechanism where an ideal voltage source 332 connects to a gate terminal of the switching transistor. This negative example serves the purpose of highlighting a common misconception in circuit design. By explicitly showing what does not work, the incorrect example implementation 330 of the conceptual contrast model 300 helps implementors avoid potential pitfalls. The ideal voltage source 332 inherently supplies whatever current to maintain its specified voltage, creating an undefined relationship between gate drive and output slew rate. The incorrect example implementation 330 of the conceptual contrast model 300 creates cognitive contrast that emphasizes decision points in the implementation process.

The third configuration is a correct example implementation 340 of a gate control logic circuit like the gate control logic circuit 222 of the example on-chip load switch circuitry 200 of FIG. 2. The correct example implementation 330 is indicated as one of the correct implementations with an affirmative checkmark 344. The correct example implementation 330 completes the educational progression of the conceptual contrast model 300 by presenting an optimized solution. Like the conceptual model 310 and the incorrect example implementation 330, the correct example implementation 340 has a switching transistor with Vᵢₙ 312 at its source node, Vₒᵤₜ 318 at its drain node, and its intrinsic capacitance element C_{gd} 316 explicitly shown as a discrete component.

The correct example implementation 330 implements a current-controlled gate drive mechanism where an ideal current source 342 delivers a constant current to a gate terminal 350. This positive example applies the mathematical relationship 320 established in the conceptual model 310 to achieve consistent, predictable results. Current-source gate control produced by the ideal current source 342 ensures that the parasitic capacitance element charges at a mathematically predictable rate, establishing a linear relationship between the supplied gate current and the resulting output voltage transition rate. The linear voltage rise is independent of an output capacitance of the circuit block.

One or more implementations of the ideal current source 342 may include a transistor with a large length-to-width ratio, which functions as a resistive element generating constant current without dedicated bias circuits. This transistor operates with channel dimensions where length exceeds width by, for example, factors ranging from 50:1 to 200:1. This creates current limitation properties derived from semiconductor physics governing charge carrier mobility across extended channel regions. The ideal current source 342 generates a gate charging current that exceeds the combined leakage components by a sufficient margin to maintain deterministic operation across process, voltage, and temperature variations, with particular attention to temperature sensitivity where leakage currents exhibit a doubling effect for every 10° C. increase in ambient conditions.

The current source 342 may alternatively include resistor-based current limiters, which utilize polysilicon or diffusion resistors to establish current ceilings that maintain predetermined flow rates regardless of connected load characteristics. Current-mirror configurations represent another implementation option for the ideal current source 342, which replicate reference currents across multiple branches through matched transistor pairs that maintain proportional current relationships despite variations in operating conditions. Voltage-controlled current sources constitute another implementation alternative for the ideal current source 342, which translates voltage differentials into proportional currents through transconductance stages that convert input voltage signals into output current flows with defined conversion ratios. The ideal current source 342 may also be realized through bootstrapped current generators, which maintain relative independence from supply voltage variations through feedback mechanisms that sense and compensate for changes in operating parameters to preserve constant output current.

### Example OLS Circuit with Voltage Distribution

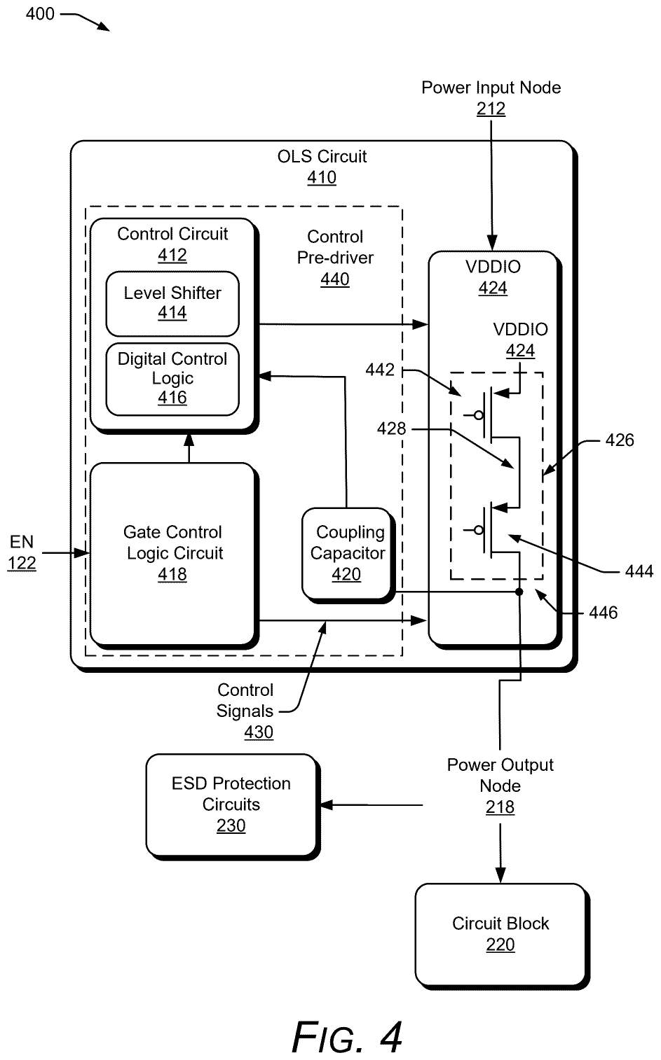

FIG. 4 illustrates an example on-chip load switch circuitry 400 that can be implemented in accordance with the technology described herein to perform voltage distribution. The on-chip load switch circuitry 400 includes the power input node (VIN) 212, the power output node (VOUT) 218, the target circuit block 220, the ESD protection circuits 230, and the EN signal 122. The OLS circuit 410 includes a switch core 422 and a control pre-driver 440.

VIN 212, VOUT 218, and the target circuit block 220 are the same as described in the on-chip load switch circuitry 200 of FIG. 2. The VIN 212 serves as the primary voltage supply interface, the VOUT 218 functions as the controlled power delivery point, and the target circuit block 220 receives operational voltage exclusively when the switch core is in its conductive state.

The ESD protection circuits 230 are the same as described in the on-chip load switch circuitry 200 of FIG. 2, connecting to VOUT 218 where it transitions between high-impedance and low-impedance states based on output voltage conditions. The ESD protection circuits 230 operates as a protective element that activates within nanoseconds when voltage transients exceed predefined thresholds, creating conduction paths that divert excess charge away from sensitive circuit components. Likewise, the EN signals 122 is the same as previously described.

The switch core 422 of the OLS circuit 410 is configured to distribute voltage stress across internal components, enabling operation at or near a defined voltage (such as 1.2V). Unlike the single transistor configuration shown in FIG. 2, the switch core 422 includes a cascode transistor stack 426 that distributes voltage stress across multiple transistors connected in series. The cascode transistor stack 426 includes top transistor A 442 and bottom transistor B 444. An input/output power supply voltage (VDDIO) 424 is provided at a drain of the top transistor A 442 of the cascode transistor stack 426.

VDDIO (Voltage Drain-Drain Input/Output) 424 functions as the primary input/output power supply voltage for the cascode transistor stack 426. The VDDIO 424 provides, for example, the 1.2V potential for the operation of target circuit blocks 220. The designation follows standard integrated circuit nomenclature, where “VDD” denotes a positive supply voltage and “IO” identifies its specific application to input/output circuitry, distinguishing it from core logic supply voltages that typically operate at lower potential.

In the cascode transistor stack 426, VDDIO 424 maintains consistent connection to the source terminal of the top transistor A 442 in the stack regardless of operational state. The VDDIO 424 serves as the voltage source that is distributed across multiple series-connected transistors (e.g., top transistor A 442 and bottom transistor B 444) due to individual device limitations in the GAA process. The 1.2V supply voltage of the VDDIO 424 may exceed the allowed voltage between terminals for individual transistors (which may be, for example, limited to 0.9V). Thus, the voltage-distributing cascode transistor stack 426 prevents any single transistor from experiencing the full voltage differential.

The top transistor A 442 and bottom transistor B 444 are arranged vertically with an intermediate node 428 positioned between them, creating a structure where neither transistor experiences the full voltage differential between VIN 212 and VOUT 218. This configuration ensures that no single transistor experiences voltage stress beyond its safe operating limits, addressing the challenge of operating at higher voltages in processes designed primarily for low-voltage operation.

The control pre-driver 440 interfaces with the switch core 422 and processes control commands while maintaining signal integrity across different voltage domains. In this voltage distribution-focused implementation, the control pre-driver 440 includes the gate control logic circuit 418, the control circuit 412, and the coupling capacitor 420.

The gate control logic circuit 418 operates within the voltage distribution framework by generating appropriate control signals 430 for both transistors in the cascode transistor stack 426. The gate control logic circuit 418 coordinates the activation timing of transistor A 442 and transistor B 444, ensuring proper voltage distribution across the intermediate node 428. This coordination maintains each transistor within its safe operating area while still enabling the switch core 422 to function as a unified switching element at the higher supply voltage. The gate control logic circuit 418 generates signals that account for the shifted ground reference, translating the EN signals 122 into appropriate gate voltages for both transistors in the cascode stack.

The control circuit 412, which couples directly to the switch core 422, operates from a shifted ground reference voltage of, for example, approximately 0.4V instead of the standard 0V reference. The shifted ground reference voltage establishes a modified operational baseline that ensures all transistors in the switch core 422 remain within safe operating area limits despite the higher overall operating voltage. The control circuit 412 includes a level shifter 414, which translates control signals between the shifted ground reference voltage domain and the full supply voltage range through voltage conversion mechanisms that preserve signal integrity across different potential references.

Additionally, the control circuit 412 includes digital control logic 416 that processes enable signals and generates appropriate control sequences for the cascode transistor stack 426. The digital control logic 416 operates entirely within the shifted ground domain to maintain consistent logical thresholds throughout the control path. The level shifter 414 interfaces between the standard ground-referenced external control signals 430 and the shifted ground-referenced digital control logic 416, creating a seamless transition between voltage domains that maintains proper timing relationships across operating conditions. This arrangement, which distributes voltage stress across multiple components rather than concentrating it within a single device, enables the OLS circuit 410 to function reliably at voltage levels that exceed the rated capabilities of individual transistors within the GAA process while maintaining device terminals within their allowed voltage specifications.

The coupling capacitor 420 is connected between the switch core 422 and the control circuit 412, providing feedback between these components. The coupling capacitor 420 is configured to clamp voltage transitions by transforming exponential voltage rises at the output node 218 (e.g., drain side 446) of the bottom transistor B 444 into a controlled linear rise. The coupling capacitor 420 mitigates potential uncontrolled voltage transitions at the output node 446. The coupling capacitor 420 transforms voltage transitions that exceed linear rates at the output node into a controlled linear rise, thereby ameliorating false triggering of ESD protection circuits.

The cascode transistor stack 426 distributes the large voltage as described above. Doing so hinders the ability to control slew rate. The coupling capacitor 420 connected at the output node 218 of the bottom transistor B 444 helps control the slew rate. The intermediate node 428 naturally exhibits a linear rise due to the aforementioned C_{gd} in the single-transistor configuration. Without the coupling capacitor 420, there would be a non-linear increase in current to flow at the output node 218 of the bottom transistor B 444, causing a faster-than-desired non-linear voltage ramp. This could lead to false triggering of ESD protection circuits 230. The coupling capacitor 420 ensures that voltage transitions remain controlled throughout operating regions, including during initial activation when transistors operate below threshold voltages.

The OLS circuit 410 implements voltage distribution through a systematic architecture that addresses inherent limitations in GAA transistor technology, which lacks true 1.2V input-output devices despite application specifications for 1.2V operation. The OLS circuit 410 performs voltage distribution by distributing stress across multiple components rather than concentrating it within individual transistors that would otherwise exceed their safe operating area constraints. The cascode transistor stack 426, which includes the transistor A 442 and the transistor B 444 connected in series with intermediate node 428 between them, forms the arrangement where voltage division occurs naturally, ensuring that neither transistor experiences the full 1.2V potential difference.

The control circuit 412 establishes the shifted ground reference voltage of approximately 0.4V, which creates a modified operational baseline that maintains all transistors within their safe operating parameters despite the higher overall operating voltage. This shifted reference point, which effectively reduces the voltage stress experienced by individual components, works in conjunction with the level shifter 414 that translates control signals 430 between the shifted ground domain and the full supply voltage range. The digital control logic 416, operating entirely within this shifted ground domain, processes the EN signals 122 and generates precisely timed control sequences for both transistors in the cascode stack while maintaining consistent logical thresholds throughout the control path.

Voltage distribution extends beyond mere static division through the incorporation of the coupling capacitor 420, which connects between the output node 218 of the switch core 422 and the control circuit 412. This capacitive coupling, which provides dynamic feedback between these components during transitional states, transforms potentially problematic exponential voltage rises at the output node 218 into controlled linear transitions that prevent false triggering of ESD protection circuits 418. The coupling capacitor 420 transforms voltage transitions that exceed linear rates at the output node 218 into a controlled linear rise, thereby ameliorating false triggering of ESD protection circuits. The coupling capacitor 420 specifically addresses the challenge that occurs when transistor A 442 operates in subthreshold regions during initial activation, where voltage at the output node 218 would otherwise rise exponentially and potentially exceed safe operating parameters.

The voltage distribution enables reliable operation at 1.2V in GAA process technology through coordinated interaction between shifted reference voltages, level translation, and capacitive feedback mechanisms. Transistor A 442 maintains a gate voltage of approximately 0.4V during active states while transistor B 444 receives the full supply voltage, creating a configuration where neither transistor exceeds its allowed voltage between any terminals. This arrangement, which converts what would be an unsafe voltage level for individual transistors into a safely distributed stress pattern across multiple devices, allows continued use of 1.2V supply for circuit blocks, such as block 418, that require this operating voltage despite the inherent limitations of advanced semiconductor processes designed primarily for lower voltage digital applications.

### Example Cascode Transistor

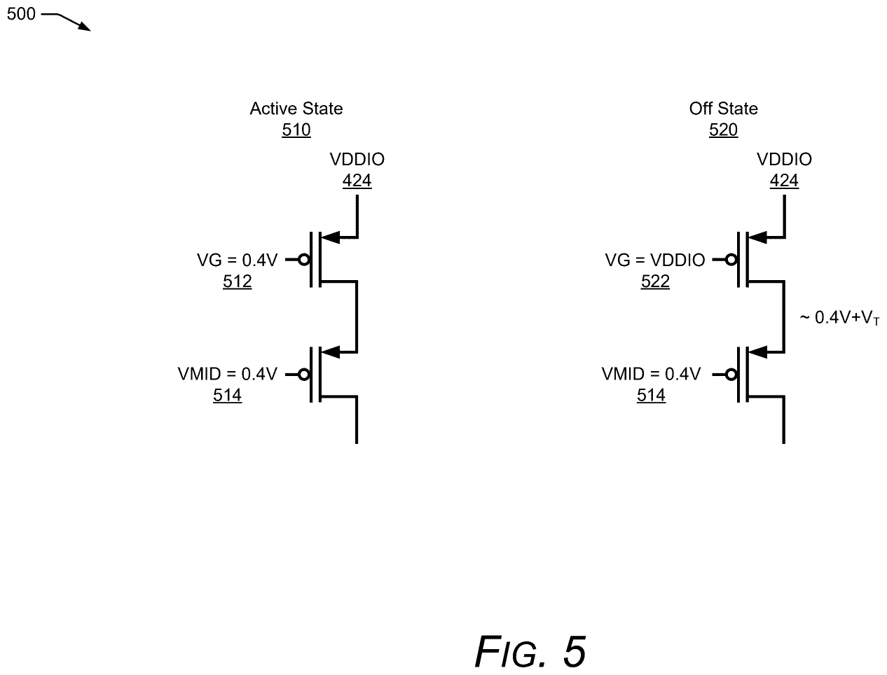

FIG. 5 illustrates an example cascode transistor stack 500 of the switch core 422 of the example OLS circuit 410 of FIG. 4. The example cascode transistor stack 500 operates in two distinct states: active state 510 and off state 520, which implement different voltage distribution patterns while maintaining safe operating parameters.

In the active state 510, demonstrates the voltage distribution mechanism that enables safe operation at 1.2V for the cascode transistor stack 500 despite limitation of individual transistor of the stack. A supply voltage VDDIO 424 supplies 1.2V a drain of the upper transistor in the cascode transistor stack 500. VDDIO 424 represents the full input/output power supply voltage that exceeds individual transistor limitations in the GAA process. A gate voltage VG 512 (e.g., 0.4V) applies to a gate the upper transistor, which creates the controlled conduction state necessary for current flow while maintaining safe voltage levels across device terminals.

The lower transistor, whose gate connects to VMID (0.4V), establishes a conduction path to ground while the upper transistor, which receives VG=0.4V at its gate terminal, conducts current from VDDIO to VMID. This configuration distributes the total 1.2V stress across both transistors, ensuring that neither transistor experiences terminal-to-terminal voltages exceeding process-imposed maximums of, for example, 0.9V which enables the cascode transistor stack 500 to function reliably within the voltage constraints of GAA technology while still providing 1.2V operational capability to downstream circuits.

Off state 520, which represents the non-conductive configuration of cascode transistor stack 500, establishes specific voltage relationships that differ from the active state 510 while maintaining safe operating conditions. The VDDIO 424 maintains its role as the input/output power supply voltage of, for example, 1.2V, which connects to the drain terminal of the upper transistor of the stack and represents the voltage that is distributed across multiple devices due to GAA process limitations.

In the off state 520, a gate voltage VG 522 of the upper transistor of the stack equals VDDIO (e.g., 1.2V), which represents the control change that differentiates the off state 520 from the active state 510 configuration.

An intermediate node voltage (VMD) 514 maintains a stable voltage (e.g., 0.4V value). VMD 514 in off state 510 rises slightly to approximately “0.4V+V_{T}”, where V_{T} represents a threshold voltage component (e.g., 0.1V-0.3V) that varies with process parameters and temperature conditions. The threshold voltage V_{T} addition to the intermediate node voltage constitutes a quantifiable electrical marker that differentiates off state 520 from active state 510, while creating a gate-to-source voltage differential in the upper transistor that prevents current conduction.

The transition processes between active state 510 and off state 520 in the cascode transistor stack 500 implement coordinated voltage manipulations that maintain terminal voltages within safe operating parameters throughout the switching sequence. Gate voltage signals, which determine the conductive properties of both transistors in the stack, follow timing patterns that prevent momentary voltage excursions beyond the 0.90V safe operating area limitations at any terminal within the cascode arrangement. The upper transistor gate voltage transitions between 0.4V during active state and VDDIO (1.2V) during off state, while the intermediate node voltage (VMID) shifts between a stable 0.4V and approximately 0.4V+V_{T}.

The coupling capacitor 420, which connects between the output node 218 and control circuitry, functions as a feedback mechanism during these transitions. This capacitance element transforms the natural exponential voltage characteristics at output node into controlled linear voltage rises through capacitive charge redistribution mechanisms that regulate voltage transition rates. Exponential voltage characteristics, which emerge naturally when transistors operate in subthreshold regions during transitional states, undergo modification through Miller multiplication effects whereby the effective capacitance at the output node increases by a factor related to the voltage gain between connected nodes.

The controlled transition approach prevents false triggering of ESD protection circuits 230 that connect to power output nodes. The coupling capacitor 460 regulation of voltage transition rates establishes linear voltage profiles that remain below ESD circuit 230 triggering thresholds while still enabling complete state transitions between conductive and non-conductive conditions (e.g., between active state 510 and off state 520). Voltage transition control occurs through charge storage and redistribution mechanisms whereby charge accumulation in the capacitor diverts current that would otherwise contribute to more rapid voltage increases at nodes within the cascode structure.

### Example Coupling Capacitor

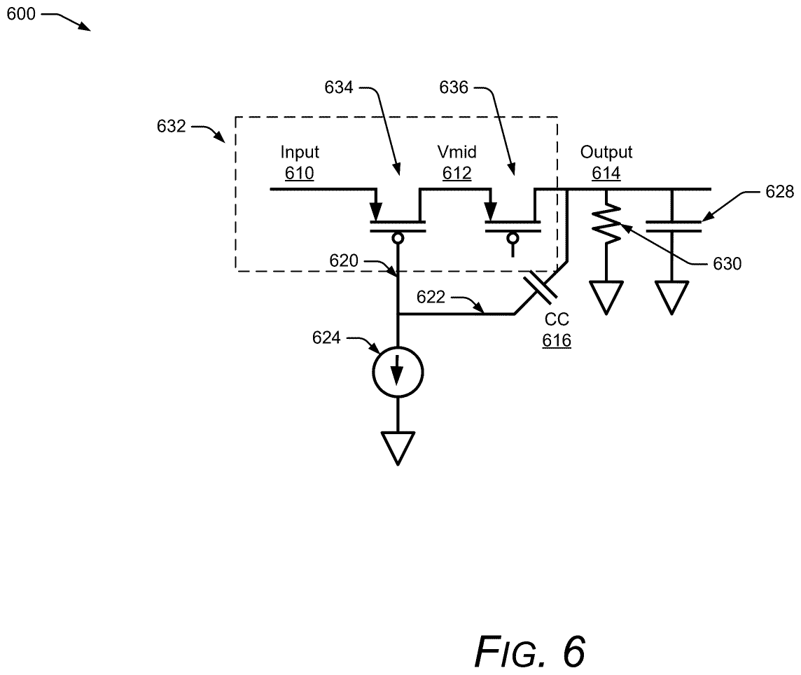

FIG. 6 illustrates simplified circuit diagram 600 of a cascode transistor stack 632 with an example coupling capacitor 616 of the example OLS circuit 400 of FIG. 4. The simplified circuit diagram 600 demonstrates how a coupling capacitor addresses a potential uncontrolled slew rate of the cascode transistor stack 632. As depicted, the circuit diagram 600 includes input 610, Vmid, 612, output 614, the cascode transistor stack 632, a common source 624, a coupling capacitor 616, and load resistance 630 and capacitance 628. The cascode transistor stack 632 includes transistor A 634 and transistor B 636.

The cascode transistor stack 632 includes transistor A 634 and transistor B 636 arranged in a vertical series configuration, implements voltage distribution whereby each transistor maintains terminal-to-terminal voltages below process-imposed maximums while collectively handling the full operational voltage. The intermediate node Vmid 612 serves as the junction point between transistor A 634 and transistor B 636, while the coupling capacitor 616 connects between gate voltage 620 and the output 614, establishing the feedback path that controls voltage transition characteristics during switching operations.

Transistor A 634 refers to the top transistor in the cascode transistor stack 632, which connects between the intermediate node Vmid 612 and the output 614. This transistor receives the input 610 at its gate terminal and functions as the common-gate device in the cascode arrangement, forming the upper portion of the voltage distribution structure. Transistor B 636 refers to the bottom transistor in the cascode stack, which connects between the common source 624 and the intermediate node Vmid 612. This transistor functions as the common-source device in the cascode arrangement and forms the lower portion of the voltage distribution structure.

Transistor B 636 functions as the output transistor because it directly connects between the intermediate node Vmid 612 and the output node 614, controlling the final delivery of current to the load. This uncontrolled voltage rise occurs because when transistor A 634 begins conducting, Vmid 612 rises linearly, causing the current through transistor B 636 to increase exponentially, which in turn creates an exponential rise in output voltage at output 614. This exponential voltage characteristic at the output 614 represents an issue that will lead to false triggering of ESD protection circuits 230.

The coupling capacitor 616 implements a feedback mechanism that addresses this uncontrolled slew rate issue limiting the gate-to-output slew rate. Consequently, there is direct correlation between capacitor value of the coupling capacitor 616 and the resulting voltage transition characteristics. As voltage begins rising at Vmid 612, coupling capacitor 616 regulates this transition through charge storage and redistribution mechanisms (e.g., a negative feedback). The charge accumulation in the coupling capacitor 616 diverts current that would otherwise contribute to rapid voltage increases, effectively clamping the voltage. This capacitive clamping transforms the natural exponential voltage rise into controlled linear transitions that prevent false triggering of ESD protection circuits 230 connected to output 614. The coupling capacitor 616 transforms voltage transitions that exceed linear rates at the output node into a controlled linear rise, thereby ameliorating false triggering of ESD protection circuits.

The load components, represented by load resistance 630 and load capacitance 628, further influence circuit behavior by presenting combined impedance characteristics that affect current demand during both steady-state operation and transitional activation sequences. Load capacitance 628 stores charge proportional to the voltage differential across its terminals, drawing current during voltage transitions according to the relationship I=C(dV/dt). This current demand profile interacts with the slew rate control mechanism established by coupling capacitor 616 that maintains controlled voltage transitions throughout operating regions of OLS circuits (such as OLS circuits 200 and 400.

The slew rate is largely independent of the output capacitor 628. In one or more implementations, this may be a desirable feature. The linear voltage rise (e.g., slew rate) is independent of an output capacitance of the circuit block. Through the aforementioned negative feedback, gate voltage 620 is automatically adjusted such that transistors 634 and 636 support the current demanded by the load, such that dVoutput/dt=Igate/CC is satisfied.

### Example Voltage-Distribution OLS with Constant-Current Slew Control

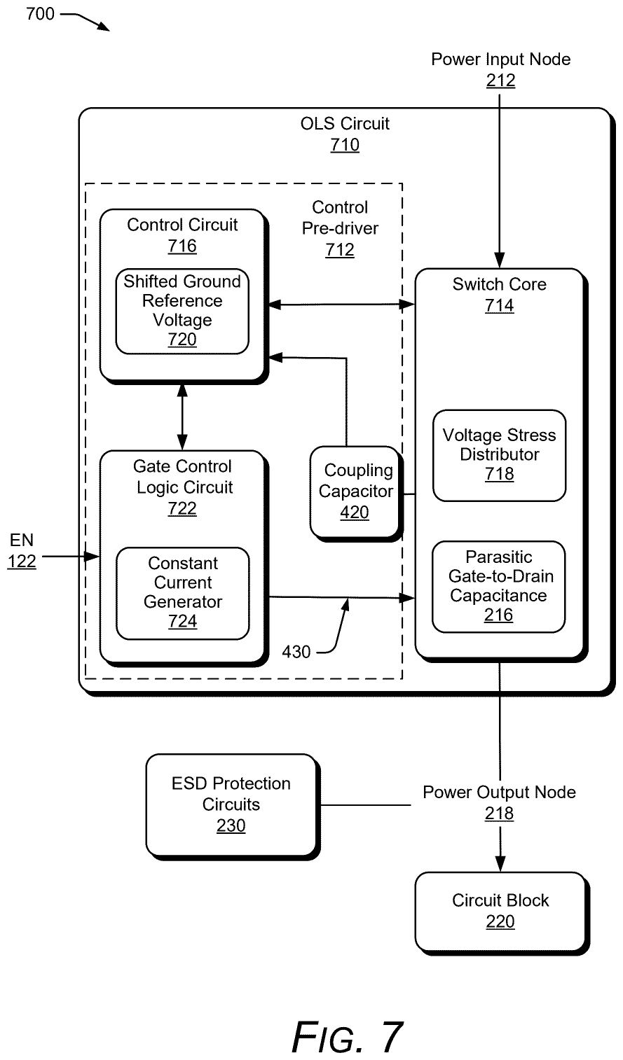

FIG. 7 illustrates an example on-chip load switch circuitry 700 that integrates voltage distribution and constant-current slew control functionalities within a single architecture, addressing dual challenges presented by GAA process technology limitations. The on-chip load switch circuitry 700 includes the power input node (VIN) 212, the power output node (VOUT) 218, the target circuit block 220, the ESD protection circuits 230, the EN signal 122, and an OLS circuit 710. The OLS circuit 710 includes a switch core 714 and a control pre-driver 712.

The switch core 714 includes the voltage-stress distributor 718 and gate-to-drawn capacitance 216. The voltage-stress distributor 718, which functions through a cascode arrangement (e.g., cascode transistor stack 426) of series-connected transistors that divide the total supply voltage across multiple devices. Each transistor within this voltage-stress distributor 718 experiences terminal-to-terminal voltages below the process-imposed 0 (e.g., of 0.90V), which maintains safe operating conditions despite the overall 1.2V operational specification. The capacitance element 216 establishes a quantifiable relationship with the constant current generator 724 according to the mathematical relationship 320, which represents the rate of change in output voltage measured in volts per microsecond.

The control pre-driver 712 includes control circuit 716, gate control logic circuit 722 and coupling capacitor 420. The control circuit 716 operates using a shifted ground reference voltage 720 (e.g., of 0.4V) rather than the standard 0V reference, which establishes a modified operational baseline that maintains all transistors within their safe operating area specifications. This voltage reference modification approach, which adjusts the effective voltage differentials experienced by individual components, enables the OLS circuit 710 to process 1.2V signals using transistors rated for lower voltages without exceeding the allowed voltage between any terminals in the GAA process.

The gate control logic circuit 722 includes a constant current generator 724, which creates a precisely defined current flow without dedicated bias circuit structures that would otherwise increase silicon area specifications. The constant current generator 724 produces a current magnitude that quantitatively exceeds the combined leakage currents present in the circuit by a margin sufficient to ensure deterministic operation across process, voltage, and temperature variations. The specific current value generated by this component, when combined with the capacitance element 216, establishes a linear voltage rise at the power output node 218 during activation sequences, which maintains slew rates within numerical parameters that prevent false triggering of the ESD protection circuits 230.

The coupling capacitor 420 performs two functions that contribute to circuit stability during transitional states. With one function, the coupling capacitor 420 addresses the uncontrolled slew rate condition that occurs when transistors in the voltage-stress distributor 718 operate in subthreshold regions during initial activation. With another function, the coupling capacitor 420 establishes a dynamic feedback path between components that transforms exponential voltage transitions into controlled linear rises through capacitive charge redistribution mechanisms. This component implements voltage transition clamping through Miller multiplication effects.

Control signals 430 coordinate the operational timing of both voltage distribution and slew rate control mechanisms through defined signal transitions. These control signals undergo level-shifting operations that maintain signal integrity across different voltage domains, which ensures accurate timing relationships throughout operational states.

During active operation, the OLS circuit 710 maintains transistor terminals within their safe operating area specifications while delivering power to the target circuit block 220 according to precisely defined sequencing parameters. The voltage-stress distributor 718 implements voltage division across multiple series-connected transistors through a cascode topology, while the constant current generator 724 establishes linear voltage transitions through its interaction with the capacitance element 216. The coupling capacitor 420, which connects between nodes in the voltage distribution path, performs the voltage waveform transformation function that converts naturally occurring exponential characteristics into controlled linear transitions without requiring dedicated bias generation circuits that occupy substantial silicon area.

### Example Method

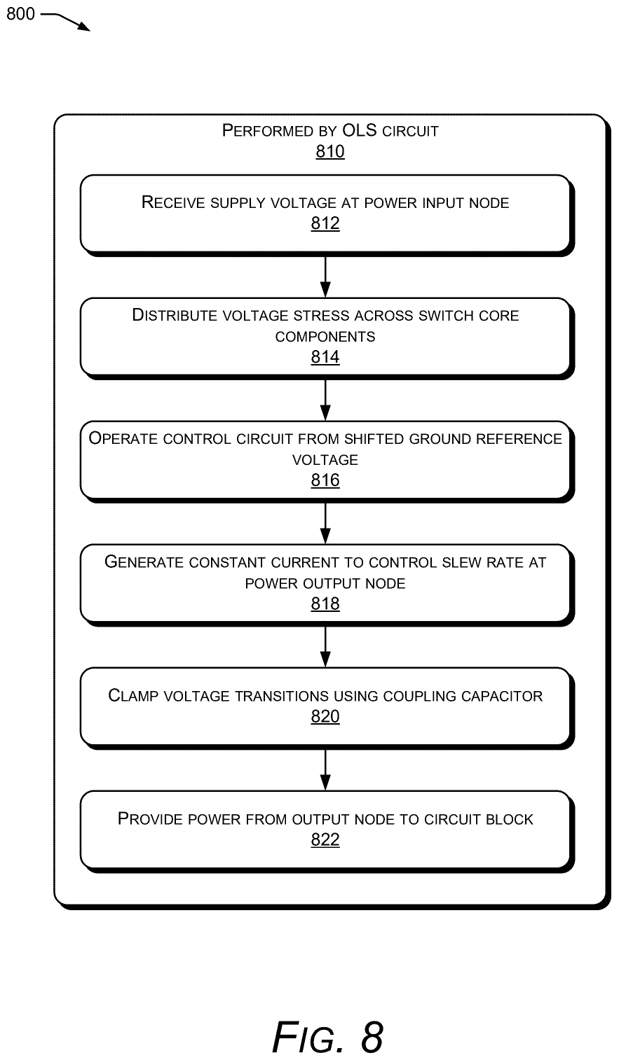

FIG. 8 illustrates an example method 800 for voltage distribution and constant-current slew control by an example OLS circuit in accordance with one or more implementations described herein. The example method 800 is performed, in whole or in part, by a suitable OLS circuit 810, such as OLS circuits 200, 400, and 700.

At 812, supply voltage is received at the power input node (e.g., power input node 212), which functions as the primary voltage supply interface for the on-chip load switch circuit. The power input node connects directly to the source terminal of the switch core (e.g., switch core 714), where it introduces the unregulated supply voltage that will undergo controlled distribution through the circuit. The power input node serves as an entry point for external power that will be subsequently regulated and distributed to internal circuit blocks, establishing the foundation for the power management functionality that follows in subsequent steps.

At 814, voltage stress is distributed across internal components of the switch core, enabling operation at or near a defined voltage of, for example, 1.2V. This distribution is implemented through a cascode transistor stack (e.g., cascode transistor stack 426) comprising transistors arranged vertically with an intermediate node (e.g., intermediate node 428) positioned between them. This configuration ensures that no single transistor experiences the full voltage differential between power input node and power output node (e.g., power output node 218), creating a structure where voltage division occurs naturally to maintain transistors within their safe operating area despite GAA process limitations that lack true 1.2V input-output devices.

At 816, the control circuit is operated from a shifted ground reference voltage of, for example, approximately 0.4V instead of the standard 0V reference. This shifted reference point establishes a modified operational baseline that ensures transistors in the switch core remain within safe operating area limits despite the higher overall operating voltage. The control circuit (e.g., control circuit 716) incorporates level-shifting functionality that translates control signals between the shifted ground reference domain and the full supply voltage range, maintaining signal integrity across different potential references in both active and off states of operation.

At 818, constant current is generated via the gate control logic circuit (e.g., gate control logic circuit 722) to control the slew rate at the power output node. The constant current charges the capacitance (e.g., capacitance element 216) within the switch core according to the mathematical relationship 320 where the rate of change in output voltage equals the current divided by the capacitance. The gate control logic circuit typically employs a transistor with a large length-to-width ratio (e.g., transistor 224) functioning as a resistive element, producing a current magnitude that deliberately exceeds leakage currents present in the gate control circuitry to maintain deterministic operation across process, voltage, and temperature variations.

At 820, voltage transitions are clamped via feedback provided between the switch core and the gate control logic circuit using a coupling capacitor (e.g., coupling capacitor 420). The coupling capacitor transforms potentially problematic exponential voltage rises at output node 218 within the switch core into controlled linear rises. This capacitive feedback mechanism addresses challenges that occur when transistors operate in subthreshold regions during initial activation, regulating transitions through charge storage and redistribution mechanisms that divert current which would otherwise contribute to more rapid voltage increases that might falsely trigger electrostatic discharge protection circuits.

At 822, power is provided from the power output node to the target circuit block. The power output node, which is coupled to the drain terminal of the switch core, serves as the controlled power delivery point of the on-chip load switch circuit, providing regulated voltage with a precisely managed slew rate to the target circuit block (e.g., target circuit block 220). The target circuit block remains in a powered-down state during deactivation periods and receives operational voltage exclusively when the switch core transitions to its conductive state, thereby enabling power consumption reduction during periods of inactivity and contributing to system-level energy efficiency.

### CONCLUSION

Although implementations of techniques for, and apparatuses enabling, performing voltage distribution and/or constant-current slew control with an OLS circuit have been described in language specific to features and/or methods, it is to be understood that the subject of the appended claims is not necessarily limited to the specific features or methods described. Rather, the specific features and methods are disclosed as example implementations for performing voltage distribution and/or constant-current slew control with an OLS circuit.

What is claimed is:

1. An on-chip load switch (OLS) circuit comprising:
a power input node configured to receive a supply voltage;
a power output node configured to provide power to a circuit block;
a switch core coupled between the power input node and the power output node, the switch core having a capacitance element; and
a gate control logic circuit coupled to the switch core, the gate control logic circuit being configured to generate a constant current to control a slew rate at the power output node based on a relationship between the constant current and the capacitance element to affect a rate of change in output voltage at the power output node.

2. The OLS circuit of claim 1, wherein the gate control logic circuit includes a transistor with a large length-to-width ratio functioning as a resistive element to generate the constant current without dedicated bias circuits.

3. The OLS circuit of claim 1, wherein the constant current generated by the gate control logic circuit exceeds leakage currents present in the gate control logic.

4. The OLS circuit of claim 1, wherein the power output node is configured to connect to Electrostatic Discharge (ESD) protection circuits.

5. The OLS circuit of claim 1, wherein the slew rate at the power output node is maintained within a predetermined range by the gate control logic circuit.

6. The OLS circuit of claim 1, wherein the switch core and the gate control logic circuit together establish a linear voltage rise at the power output node during activation of the switch core through the relationship between the constant current and the capacitance element, the linear voltage rise being independent of an output capacitance of the circuit block.

7. The OLS circuit of claim 1, wherein the switch core comprises a metal-oxide-semiconductor field-effect transistor (MOSFET) transistor, and the capacitance element is between the gate and drain terminals of the MOSFET transistor.

8. An on-chip load switch (OLS) circuit comprising:
a power input node configured to receive a supply voltage;
a power output node configured to provide power to a circuit block;
a switch core coupled between the power input node and the power output node, the switch core being configured to distribute voltage stress across internal components of the switch core to enable operation at or near a defined voltage;
a control circuit coupled to the switch core, the control circuit configured to operate from a shifted ground reference voltage and facilitate the voltage-stress distribution of the switch core;
a gate control logic circuit coupled to the switch core; and
a coupling capacitor coupled between the switch core and the gate control logic circuit, the coupling capacitor configured to clamp voltage transitions by providing feedback between the switch core and the gate control logic circuit.

9. The OLS circuit of claim 8, wherein the defined voltage is 1.2 V.

10. The OLS circuit of claim 8, wherein the switch core includes a cascode transistor stack having at least first and second transistors connected in series to distribute the voltage stress across the internal components of the switch core, wherein the coupling capacitor is connected between the power output node and a control node of the gate control logic circuit.

11. The OLS circuit of claim 8, wherein the control circuit operates from a shifted ground reference voltage of approximately 0.4V instead of 0V to maintain transistors within safe operating area limits.

12. The OLS circuit of claim 10, wherein the coupling capacitor transforms voltage transitions that exceed linear rates at the output node into a controlled linear rise to ameliorate false triggering of Electrostatic Discharge (ESD) protection circuits.

13. The OLS circuit of claim 8, wherein the control circuit includes a level shifter that translates control signals between the shifted ground reference voltage of approximately 0.4V and the full supply voltage range.

14. An on-chip load switch (OLS) circuit comprising:
a power input node configured to receive a supply voltage;
a power output node configured to provide power to a circuit block;
a switch core coupled between the power input node and the power output node, the switch core being configured to distribute voltage stress across internal components of the switch core to enable operation at or near a defined voltage, the switch core having a capacitance element;
a control circuit coupled to the switch core, the control circuit configured to operate from a shifted ground reference voltage and facilitate the voltage-stress distribution of the switch core;
a gate control logic circuit coupled to the switch core, the gate control logic circuit being configured to generate a constant current to control a slew rate at the power output node, wherein a relationship between the constant current and the capacitance element determines a rate of change in output voltage at the power output node, the linear voltage rise being independent of an output capacitance of the circuit block; and
a coupling capacitor coupled between the switch core and the gate control logic circuit, the coupling capacitor configured to clamp voltage transitions by providing feedback between the switch core and the gate control logic circuit.
